(19) United States
(12) Patent Application Publication
(10) Pub. No.: US 2026/0026277 A1
(43) Pub. Date: Jan. 22, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Jeongmin CHA, Suwon-si (KR); Songyun KANG, Suwon-si (KR); Hyeukjin SEO, Suwon-si (KR); Jiwon SON, Suwon-si (KR); Kukhan YOON, Suwon-si (KR); Iseul JANG, Suwon-si (KR)

(73) Assignee: Samsung Electronics Co., Ltd., Suwon-si (KR)

(21) Appl. No.: 19/077,596

(22) Filed: Mar. 12, 2025

(30) Foreign Application Priority Data
Jul. 18, 2024 (KR) 10-2024-0094823
Sep. 5, 2024 (KR) 10-2024-0120614

(51) Int. Cl. H01L 21/311; H01J 37/32; H01L 21/67; H01L 21/768

(52) U.S. Cl. CPC H01L 21/31116; H01J 37/3244; H01L 21/31144; H01L 21/67069; H01L 21/76802; H01L 21/76877; H01J 2237/334

(57) ABSTRACT

A method of manufacturing a semiconductor device includes providing a substrate including a molded structure and a mask layer on the molded structure, loading the substrate into an etching process chamber, performing an etching process on the loaded substrate and forming a plurality of recesses penetrating at least a portion of the molded structure, unloading the substrate from the etching process chamber, and performing a second semiconductor process on the unloaded substrate. The performing the etching process includes supplying an etching process gas including a first process gas and a second process gas including a fluorine-containing gas. In the forming the plurality of recesses, first by-products are formed. Second by-products are formed by a reaction of at least a portion of the first by-products and the second process gas.

### CROSS-REFERENCE TO RELATED APPLICATION(S)

This application claims the benefit under 35 USC 119 (a) of Korean Patent Application No. 10-2024-0094823 filed on Jul. 18, 2024 and Korean Patent Application No. 10-2024-0120614 filed on Sep. 5, 2024 in the Korean Intellectual Property Office, the entire disclosures of which are incorporated herein by reference for all purposes.

### BACKGROUND

The present inventive concepts relate to a semiconductor device, a method of manufacturing the same, and a substrate processing apparatus configured to perform the method.

As the demand for high performance, high speed, and/or multifunctionality of semiconductor devices increases, the integration of semiconductor devices is increasing. In manufacturing semiconductor devices with fine patterns corresponding to the trend toward high integration of semiconductor devices, implementing patterns having fine widths and/or fine spacings consistently is beneficial.

### SUMMARY

Example embodiments provide a semiconductor device having improved electrical characteristics and/or reliability.

According to example embodiments, a method of manufacturing a semiconductor device includes providing a substrate comprising a molded structure and a mask layer on the molded structure, the mask layer having an opening of a first width; loading the substrate into an etching process chamber; performing an etching process on the loaded substrate such that a plurality of recesses penetrating at least a portion of the molded structure are formed; unloading the substrate having undergone the etching process from the etching process chamber; and performing a semiconductor process on the unloaded substrate. The performing the etching process includes supplying an etching process gas comprising a first process gas and a second process gas into the etching process chamber through a gas supply source connected to the etching process chamber, the second process gas including a fluorine-containing gas. In the forming the plurality of recesses, first by-products are formed and second by-products are formed by a reaction of at least a portion of the first by-products and the second process gas.

According to example embodiments, a method of manufacturing a semiconductor device includes providing a substrate comprising a lower structure, a stack structure including first layers and second layers alternately stacked on the lower structure, and a mask layer on the stack structure, the mask having an opening of a first width; loading the substrate into an etching process chamber; performing an etching process on the loaded substrate such that a plurality of recesses penetrating at least a portion of the stack structure are formed; unloading the substrate having undergone the etching process from the etching process chamber; and performing a semiconductor process on the unloaded substrate. The performing the etching process includes controlling a temperature of a chiller connected to the etching process chamber to be below zero degrees Celsius (0° C.), and supplying an etching process gas including a first process gas and a second process gas the etching process chamber through a gas supply source connected to the etching process chamber, the second process gas including at least one of boron trifluoride (BF₃) or nitrogen trifluoride (NF₃). First by-products are formed by forming the plurality of recesses, and second by-products are formed by a reaction of at least a portion of the first by-products and the second process gas.

According to example embodiments, a method of manufacturing a semiconductor device includes providing a substrate comprising a lower structure, a stack structure including first layers and second layers alternately stacked on the lower structure, and a mask layer on the stack structure, the mask having an opening; loading the substrate into an etching process chamber; performing an etching process on the loaded substrate such that a plurality of recesses penetrating at least a portion of the stack structure are formed; unloading the substrate having undergone the etching process from the etching process chamber; and performing a semiconductor process on the unloaded substrate. The performing the etching process includes controlling a temperature of a chiller connected to the etching process chamber to be below zero (0° C.; and supplying an etching process gas including a first process gas and a second process gas into the etching process chamber through a gas supply source connected to the etching process chamber, the first process gas containing at least one of hydrogen or hydrofluoric acid, and the second process gas containing at least one of boron trifluoride (BF₃) or nitrogen trifluoride (NF₃). First by-products and second by-products are sequentially formed by forming the plurality of recesses. The first by-products are formed by a reaction of the first process gas and the stack structure, and the second by-products are formed by a reaction of at least a portion of the first by-products and the second process gas.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a cross-sectional view of a substrate processing apparatus according to at least one embodiment;

FIGS. 2A to 2C are flowcharts illustrating a method of manufacturing a semiconductor device according to at least one embodiment in accordance with a process sequence;

FIGS. 3, 4A, 4B, 4C, and 5 are cross-sectional views illustrating a method of manufacturing a semiconductor device according to at least one embodiment;

FIG. 6 is a plan view of a semiconductor device according to at least one embodiment;

FIG. 7 is an enlarged view of a portion of the semiconductor device illustrated in FIG. 6;

FIG. 8 is vertical cross-sectional views taken along line I-I′ of the semiconductor device illustrated in FIG. 6;

FIGS. 9A to 9C are flowcharts illustrating a method of manufacturing a semiconductor device according to at least one embodiment in accordance with a process sequence; and

FIGS. 10 to 13 are cross-sectional views illustrating a method of manufacturing a semiconductor device according to at least one embodiment.

### DETAILED DESCRIPTION

Hereinafter, spatially relative terms such as “on,” “upper,” “upper surface,” “below,” “lower,” “low surface,” “side,” “side surface,” “top,” “bottom,” and the like are understood to refer to the drawings, except in cases where they are separately referred to by being indicated with drawing symbols. Thereby, it will be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly. Additionally, terms such as “upper,” “middle,” “intermediate,” and “lower” may also be replaced with other terms, such as “first,” “second,” and “third,” and used to describe components of the specification. Terms such as “first,” “second,” and “third” may be used to describe various components, but the components are not limited by the terms. These terms are only used to distinguish one component from another.

Hereinafter, example embodiments will be described with reference to the attached drawings wherein like reference numerals refer to like elements throughout. In this regard, the present embodiments may have different forms and should not be construed as being limited to the descriptions set forth herein. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometric. When referring to range of “C to D”, this means C inclusive to D inclusive unless otherwise specified.

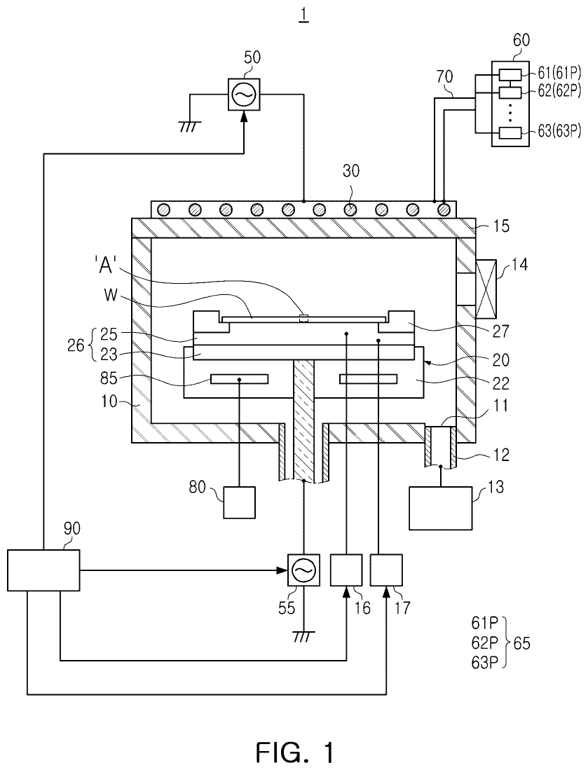

FIG. 1 is a cross-sectional view of a substrate processing apparatus according to at least one embodiment.

Referring to FIG. 1, a substrate processing apparatus 1, according to at least one embodiment, includes a process chamber 10, a substrate stage 20, an upper electrode 30, plasma generation units 50 and 55, a gas supply source 60, a chiller 80, and a control unit 90.

The process chamber 10 may be configured to provide a sealed space for plasma processing a substrate W. In at least one embodiment, the process chamber 10 may be referred to as a plasma etching process chamber and/or an etching process chamber. An exhaust port 11 and an exhaust pipe 12 may be installed in a bottom of the process chamber 10. The process chamber 10 may be connected to an exhaust unit 13 through the exhaust pipe 12. The exhaust unit 13 may include a vacuum pump configured to control the pressure inside the process chamber 10 to a preset vacuum level. A gate 14 for entry and exit of the substrate W may be disposed on the side wall of the process chamber 10. A window 15 may be disposed on the upper portion of the process chamber 10. The window 15 may constitute the entire or a portion of the upper portion of the process chamber 10. In at least some embodiments, the window 15 may include an insulating material such as alumina (Al₂O₃). The window 15 may be configured to be transparent to a magnetic field generated by a current flowing in the upper electrode 30.

The substrate stage 20 may be disposed within the process chamber 10. The substrate stage 20 may include a support member 22, a pedestal 26, and an edge ring 27. The pedestal 26 may include a lower electrode 23 and a fixed chuck 25. The substate stage 20 may be configured to receive and/or hold the substrate W.

The lower electrode 23 may be disposed on the support member 22. The lower electrode 23 may have a disc shape. The lower electrode 23 may include a conductive (e.g., zero-band gap) material (e.g., a metal such as, for example, aluminum (Al), titanium (Ti), stainless steel, tungsten (W), alloys thereof, and/or the like).

The fixed chuck 25 may be placed on the lower electrode 23. The fixed chuck 25 may include an electrostatic chuck (ESC) including a dielectric layer and an adsorption electrode. For example, the dielectric layer may include a dielectric material such as an aluminum oxide layer (Al₂O₃), an aluminum nitride layer (AlN), an yttrium oxide layer (Y₂O₃), a resin, and/or the like. The adsorption electrode may include a metal such as tungsten (W), copper (Cu), nickel (Ni), or the like, and/or a conductor such as tungsten carbide (WC). The electrostatic chuck may be electrically connected to an electrostatic chuck power supply unit 16 and a control unit 90. A DC voltage is applied to the adsorption electrode of the electrostatic chuck from the electrostatic chuck power supply unit 16, and electrostatic force is generated between the adsorption electrode and the substrate W, so that the substrate W may be adsorbed on the electrostatic chuck.

The fixed chuck 25 may include a heater (not illustrated) therein. The heater may include a heater dielectric layer including a dielectric, and a heater electrode including a conductor. The heater may be electrically connected to a heater power supply unit 17 and the control unit 90. For example, the temperature of the fixed chuck 25 and the substrate W may be controlled by heating of the heater electrode due to the alternating current voltage supplied from the heater power supply unit 17 to the heater.

The substrate W may be placed on the pedestal 26. The edge ring 27 may be placed on the outer periphery of the substrate W on the pedestal 26. The edge ring 27 may include, for example, a conductive material and an insulating material. The edge ring 27 may be configured to improve the uniformity of the substrate W etching.

The upper electrode 30 may be placed on the window 15 so as to face the lower electrode 23. The space between the upper electrode 30 and the lower electrode 23 may be a plasma generation space. The upper electrode 30 may include a high-frequency antenna. The high-frequency antenna may include an inductively coupled antenna.

The plasma generation unit may be placed outside the process chamber 10. The plasma generation unit may include a high-frequency power supply unit 50 and a bias power supply unit 55. The high-frequency power supply unit 50 may be electrically connected to the upper electrode 30. The high-frequency power supply unit 50 is configured to output high-frequency power suitable for plasma generation. The high-frequency power supply unit 50 may include a high-frequency power source and an impedance matcher.

The bias power supply 55 may be electrically connected to the lower electrode 23. The bias power supply 55 is configured to apply ahigh-frequency power to the lower electrode 23, and the lower electrode 23 may serve as an electrode for plasma generation.

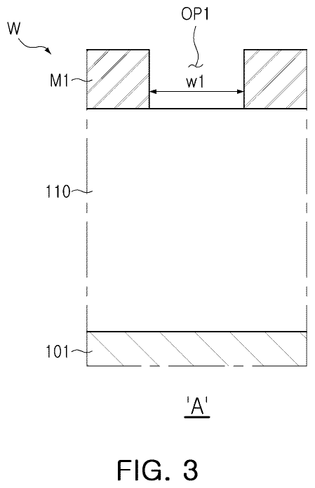

The gas supply source 60 may be connected to the process chamber 10 through the gas supply pipe 70. The gas supply source 60 may supply the process gas 65 to the process chamber 10. The process gases 65 may include a plurality of process gases 61P, 62P and 63P. The gas supply source 60 may include a first process gas supply source 61 that supplies a first process gas 61P selected to etch a material layer on a substrate W, a second process gas supply source 62 that supplies a second process gas 62P that is selected to significantly reduce or prevent clogging of an opening (see ‘OP1’ of FIG. 3) of a mask layer (see ‘M1’ of FIG. 3), and a third process gas supply source 63 that supplies a third process gas 63P selected to control the concentration of the first and second process gases 61P and 62P.

The chiller 80 may be connected to the process chamber 10. A temperature of the chiller 80 may be controlled using a temperature detection signal output from a temperature detection sensor that detects the temperature. A coolant path 85 is formed inside the support member 22, and a refrigerant inlet pipe and a refrigerant outlet pipe are connected to the coolant path 85. The coolant output from the chiller 80 may circulate through the coolant inlet pipe, the coolant path 85, and the coolant outlet pipe. The support member 22 and the substrate W loaded on the support member 22 may be cooled by the coolant. The cooling temperature of the loaded substrate W may be formed lower than the temperature of the chiller 80.

The control unit 90 may control the high-frequency power supply unit 50, the bias power supply unit 55, the electrostatic chuck power supply unit 16, and the heater power supply unit 17. The control unit 90 may include processing circuitry, such as hardware, software, or a combination of hardware and software, configured to control the operation of the substrate processing apparatus 1. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. In at least one embodiment, the control unit 90 includes a microcomputer and various interfaces, and may control the plasma treatment operation according to the program and recipe information stored in the external memory or the internal memory.

In order for the substrate treatment device 1 to perform the etching process, the substrate W may be mounted on the electrostatic chuck in the process chamber 10 through the gate 14. Power is supplied to the electrostatic chuck from the electrostatic chuck power supply unit 16, and the substrate W may be adsorbed on the electrostatic chuck by the electrostatic force generated thereby. An etching gas may be introduced into the process chamber 10 from the gas supply unit 60. The exhaust unit 13 may control the pressure inside the process chamber 10 by using a vacuum pump. The high-frequency power supply unit 50 may supply power from a high-frequency power source to the upper electrode 30 through an impedance matcher. The bias power supply unit 55 may supply power to the lower electrode 23. The etching gas introduced into the process chamber 10 may be uniformly diffused inside the process chamber 10 under the window 15. A magnetic field is generated by the current flowing in the upper electrode 30 and the high-frequency antenna, and the magnetic force lines may penetrate the window 15 and pass through the inside of the process chamber 10. An induced electric field is generated according to the temporal change of the magnetic field, and thereby a plasma may be generated by electrons accelerated by the induced electric field colliding with molecules or atoms of the etching gas.

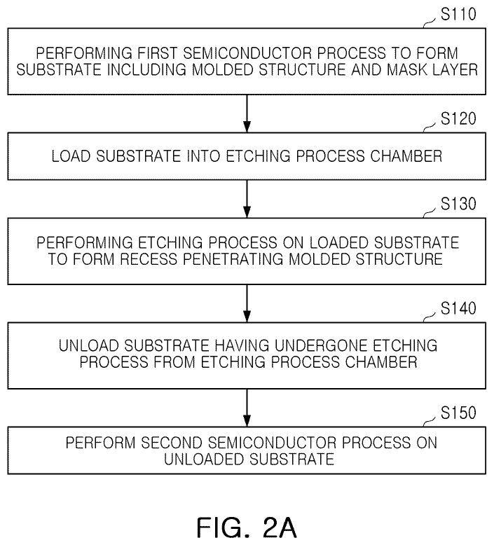

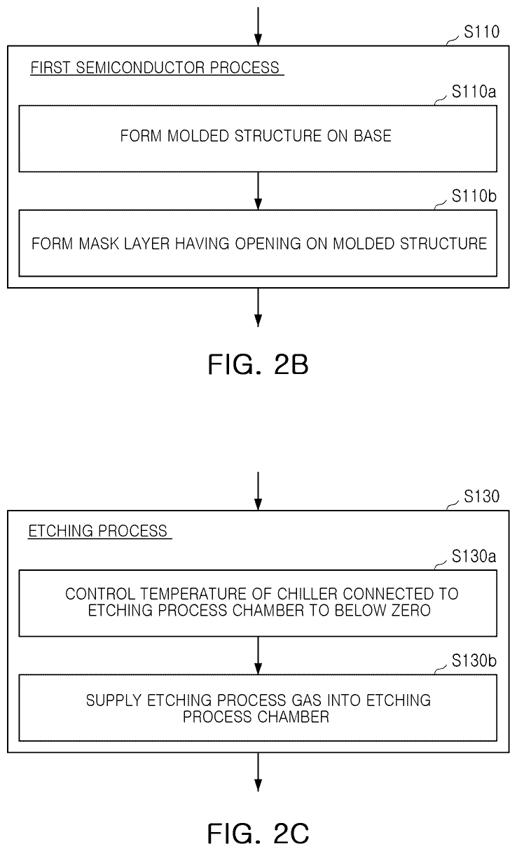

FIGS. 2A to 2C are flowcharts illustrating a method of manufacturing a semiconductor device according to at least one embodiment in the order of processes.

Referring to FIG. 2A, manufacturing a semiconductor device 100 may include performing a first semiconductor process to form a substrate including a molded structure and a mask layer (S110), loading the substrate into an etching process chamber (S120), performing an etching process on the loaded substrate to form a recess penetrating the molded structure (S130), unloading the substrate on which the etching process has been performed from the etching process chamber (S140), and performing a second semiconductor process on the unloaded substrate (S150).

Referring to FIG. 2B, in operation S110, performing the first semiconductor process may include forming a molded structure on a base (S110a), and forming a mask layer having an opening on the molded structure (S110b).

Referring to FIG. 2C, in operation S130, performing the etching process may include controlling the temperature of a chiller connected to the etching process chamber to below zero degrees Celsius (0° C.) (S130a), and supplying an etching process gas into the etching process chamber (S130b).

Each of the operations (S110-S150) may be described with reference to FIGS. 3, 4A, 4B, 4C, and 5.

At least a part of manufacturing a semiconductor device 100 may be performed in a substrate processing apparatus 1 described with reference to FIG. 1.

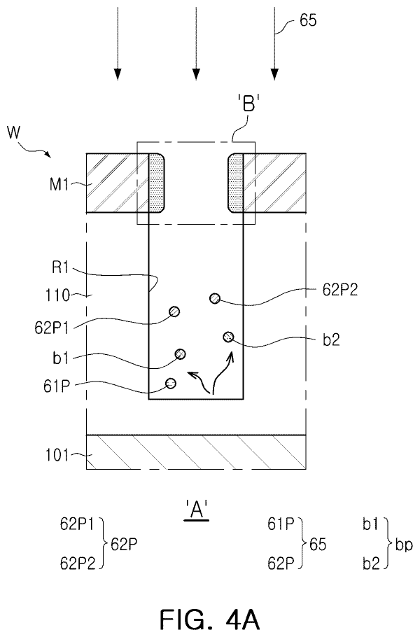

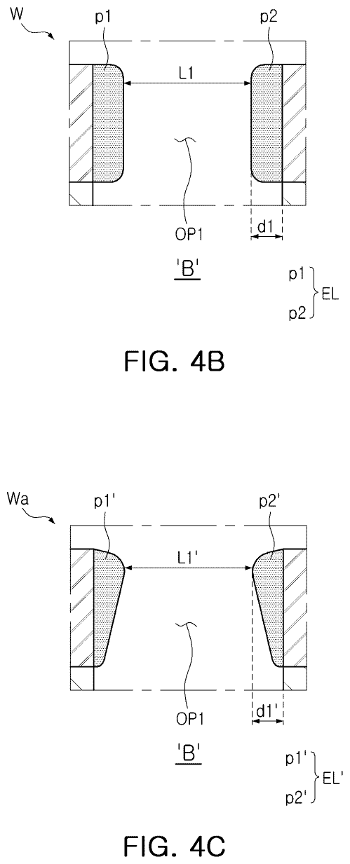

FIGS. 3, 4A, 4B, 4C, and 5 are cross-sectional views for describing a method of manufacturing a semiconductor device according to at least one embodiment. FIGS. 4B and 4C are enlarged views of a portion of the substrate W illustrated in FIG. 4A corresponding to area B. FIG. 3, FIG. 4A, FIG. 4B, FIG. 4C, and FIG. 5 may be process diagrams based on the flow charts of FIG. 2A to FIG. 2C.

Referring to FIG. 2A and FIG. 3, a first semiconductor process may be performed to form a substrate W including a molded structure 110 and a mask layer M1 (S110).

Referring to FIG. 2B, the first semiconductor process may include forming a molded structure 110 on a base 101 (S110a).

Referring to FIG. 3, the base 101 may include a semiconductor material, such as a group IV semiconductor, a group III-V compound semiconductor, and/or a group II-VI compound semiconductor. For example, the group IV semiconductor may include silicon, germanium, and/or silicon-germanium. The base 101 may further include impurities, e.g., dopants. The base 101 may be a silicon substrate, a silicon-on-insulator (SOI) substrate, a germanium substrate, a germanium-on-insulator (GOI) substrate, a silicon-germanium substrate, a substrate including an epitaxial layer, and/or the like.

A molded structure 110 may be formed on the base 101. The molded structure 110 may be formed of an insulating material including an insulating oxide and/or an insulating nitride. The molded structure 110 may be, for example, silicon oxide, silicon nitride, a combination thereof, and/or the like. The molded structure 110 may be formed through a deposition process. The molded structure 110 may be formed using, for example, chemical vapor deposition (CVD) or physical vapor deposition. The molded structure 110 may include an oxide and/or nitride of the semiconductor material in the base 101 and/or may include an oxide and/or nitride of a material different from the base 101.

Referring to FIG. 2B, the first semiconductor process may include forming a mask layer M1 having an opening OP1 on the molded structure 110 (S110b).

Referring to FIG. 3, a patterned mask layer M1 may be provided on the molded structure 110. The patterned mask layer M1 may have an opening OP1 having a first width w1. The mask layer M1 may be a metal-containing mask layer formed of a metal-containing material. The metal-containing material may include a transition metal. The metal-containing material may include, for example, titanium nitride, tungsten, tungsten carbide, and/or the like. The metal-containing material of the mask layer M1 may be selected as a material with etch selectivity compared to the molded structure 110.

The opening OP1 may include a plurality of openings spaced apart in a direction parallel to the upper surface of the base 101. The first width w1 may be about 20 nanometers (nm) or less. In at least one embodiment, the first width w1 may be about 5 nm or more and/or about 20 nm or less. In at least one embodiment, the first width w1 may be in a range of about 7 nm to about 20 nm.

Referring again to FIG. 2A, the substrate W may be loaded onto the electrostatic chuck of the process chamber 10 through the gate (refer to ‘14’ of FIG. 1) (S120).

Referring to FIGS. 2A, 4A, and 4B, an etching process may be performed on the loaded substrate W to form a recess RI penetrating at least a portion of the molded structure 110 (S130).

Referring to FIG. 2C, the etching process may include controlling the temperature of the chiller 80 connected to the process chamber 10 to be below zero (0)° C. (S130a).

Referring to FIG. 1, the operation (S130a) of controlling the temperature of the chiller 80 connected to the process chamber 10 to 0° C. zero may be performed by measuring and determining the temperature of the chiller 80 using a temperature detection signal output from a temperature detection sensor that detects the temperature of the chiller 80. The temperature may be a temperature within a range of about negative eighty (−80)° C. to about negative thirty-five (−35)° C.

The coolant output from the chiller 80 circulates through the coolant inlet pipe, the coolant path 85, and the coolant outlet pipe, and the substrate W loaded on the electrostatic chuck may be cooled by the coolant.

The degree of cooling of the loaded substrate W may be lower than the degree of cooling of the chiller 80. As such, the cooling temperature of the loaded substrate W may be higher than the temperature of the chiller 80. In at least one embodiment, the surface temperature of the loaded substrate W may be a temperature within a range of about negative sixty (−60)° C. to about zero (0)° C. In at least one embodiment, the surface temperature of the loaded substrate W may be a temperature within a range of about negative forty (−40)° C. to about negative ten (−10)° C. In at least one embodiment, the median value of the surface temperature of the loaded substrate W may be negative twenty-five (−25)° C. When the surface temperature of the loaded substrate W is below zero, the etching process may be performed at a higher etching rate compared to when the surface temperature of the loaded substrate W is at room temperature.

Referring to FIG. 2C, FIG. 4A and FIG. 4B, the etching process may include supplying a process gas 65 into the process chamber 10 (S130b).

Referring to FIG. 1, a process gas 65 may be supplied into the process chamber 10 through a gas supply pipe 70. The process gas 65 may be a gas mixture in which first to third process gases 61P, 62P and 63P of first to third process gas supply sources 61, 62 and 63 are mixed.

The first process gas 61P may include a material (or composition) that etches the molded structure 110. In at least one embodiment, the first process gas 61P may include a hydrogen-containing gas. The first process gas 61P may include, for example, at least one of hydrogen gas and/or hydrofluoric acid. In at least one embodiment, the first process gas 61P may be referred to as a main etching gas, and the first process gas supply source 61 may be referred to as a main etching gas supply source.

The second process gas 62P may include a material (or composition) that assists the etching process. In at least some embodiment, the second process gas 62P may include a fluorine-containing gas. The second process gas 62P may include at least one of first gas components 62P1 and/or second gas components 62P2. The first gas component 62P1 may contain boron. The first gas component 62P1 may include, for example, boron trifluoride (BF₃). The second gas component 62P2 may contain nitrogen. The second gas component 62P2 may include, for example, nitrogen trifluoride (NF₃). In at least one embodiment, the second process gas 62P may be referred to as an auxiliary gas, and the second process gas supply source 62 may be referred to as an auxiliary gas supply source.

The third process gas 63P may include a substance (or composition) for controlling the concentration of the first and second process gases 61P and 62P. The third process gas 63P may include, for example, an inert gas. The third process gas supply source 63 may be referred to as an inert gas supply source.

The mole fraction of the second process gas 62P relative to the process gas 65 may be about 30 mol % or less. In at least one embodiment, the mole fraction may be in a range of about 0.01 mol % to about 30 mol %. In at least one embodiment, the mole fraction may be in a range of about 0.01 mol % to about 10 mol %. In at least one embodiment, the molar fraction may be in the range of about 0.03 mol % to about 5 mol %.

The molar ratio of the second process gas 61P to the first process gas 62P may be about 0.2 times or less. In at least one embodiment, the molar ratio may be in the range of about 0.01 times to about 0.2 times. In at least one embodiment, the molar ratio may be in the range of about 0.03 times to about 0.1 times.

When the second process gas 62P includes both the first and second gas components 62P1 and 62P2, the molar ratio of the first gas component 62P1 to the second gas component 62P2 may be about 1.0 times or more. In at least one embodiment, the molar ratio of the first gas component 62P1 to the second gas component 62P2 may be in the range of about 1.0 times to about 3.0 times. In at least one embodiment, the molar ratio of the first gas component 62P1 to the second gas component 62P2 may be in the range of about 1.5 times to about 2.5 times. In at least one embodiment, the molar ratio of the first gas component 62P1 to the second gas component 62P2 may be about 2.0 times.

Meanwhile, the process gas 65 may not include a carbon-containing gas.

Referring again to FIGS. 2A, 4A, and 4B, a recess R1 penetrating at least a portion of the molded structure 110 may be formed by the process gas 65 (S130).

The recess R1 may be formed by the process gas 65. The recess R1 may be formed by etching the molded structure 110 exposed by the opening OP1 by the first process gas 61P. First by-products bp may be formed. The first by-products bp may be gaseous materials formed when the molded structure 110 is etched by the first process gas 61P. The first by-products bp may include, for example, a gas b1 containing nitrogen and/or a gas b2 containing oxygen. For example, when the molded structure 110 includes an insulating nitride, at least a portion b1 of the first by-products bp may include, for example, ammonia (NH₃); and/or when the molded structure 110 includes an insulating oxide, at least a portion b2 of the first by-products bp may include, for example, water vapor (H₂O).

An edge layer EL may be formed by the process gas 65. The edge layer EL may be formed on a sidewall of the opening OP1. The edge layer EL may be formed by at least a portion of the second process gas 62P reacting with a material of the mask layer M1. In another aspect, the edge layer EL may be formed by at least a portion of the second process gas 62P physically and/or chemically bonding with the mask layer M1. In a comparative example, the first by-products bp may react with a metal material of the mask layer M1, thereby forming a residue layer formed of a metal oxide, a metal nitride, and/or a metal oxynitride on the sidewall of the opening OP1. Accordingly, the first width (‘w1’ in FIG. 3) of the opening OP1 may be narrowed and/or completely closed. The edge layer EL may maintain the etch rate for the molded structure 110 by significantly reducing and/or preventing the phenomenon of opening blocking. The edge layer EL may include, for example, boron nitride.

At least a portion of the second process gas 62P and the first by-products bp may react to form second by-products. At least a portion of the second process gas 62P may react with the first by-products bp, thereby significantly reducing or eliminating the amount of the first by-products bp that may react with the material of the mask layer M1. The second by-products may include, for example, at least one of boron trifluoride ammonia complex (BF₃·NH₃) or boric acid (H₃BO₃).

Referring to FIG. 4B, the edge layer EL may include a first portion p1 formed on a first side of the opening OP1 and a second portion p2 formed on a second side facing the first side. A first distance L1, which is a minimum distance between the first and second portions p1 and p2, may be equal to about 0.5 or more times the first width (see ‘w1’ of FIG. 3). In at least one embodiment, the first distance L1 may be in a range of about 0.5 times to about 0.9 times the first width w1. In at least one embodiment, the first distance L1 may be in a range of about 0.5 times to about 0.8 times the first width w1.

The first thickness d1, which is at least one maximum thickness of the first and second portions p1 and p2, may be about 5 nm or less. In at least one embodiment, the first thickness d1 may be in a range of about 1 nm to about 5 nm. In at least one embodiment, the first thickness d1 may be in a range of about 2 nm to about 5 nm.

Referring to FIG. 4C, in the processing process for a substrate Wa, the first and second portions pl′ and p2′ of the edge layer EL′ may be formed asymmetrically, which may be the same as or similar to that described with reference to FIG. 3, FIG. 4A, and FIG. 4B.

Referring to FIG. 4C, the first distance L1′, which is the minimum distance between the first and second portions p1′ and p2′, may be defined in the upper region of the edge layer EL′. From another perspective, the first thickness d1′, which is at least one maximum thickness of the first and second portions p1′ and p2′, may be defined in the upper region of the edge layer EL′.

Thereafter, referring back to FIG. 2A, the substrate W on which the etching process has been performed may be unloaded from the electrostatic chuck and removed from the process chamber 10 through the gate (refer to ‘14’ of FIG. 1) (S140).

Referring to FIG. 2A and FIG. 5, a second semiconductor process may be performed on the unloaded substrate W to form a semiconductor device 100 (S150).

The second semiconductor process may include, for example, a process of removing a mask layer (‘M1’ of FIG. 4) from the unloaded substrate W. The mask layer (‘M1’ of FIG. 4 may be removed by, for example, a dry process using a wet chemical agent or plasma. In these cases, the edge layer (‘EL’ in FIG. 4) may be removed together. The process of removing the mask layer may be referred to as a stripping process.

The second semiconductor process may include a plurality of semiconductor processes. For example, a process of filling a conductive material in a recess RI to form a metal wiring may be performed subsequent to the stripping process. Then, a planarization process for planarizing a surface formed by the stripping process and the metal wiring process may be performed subsequent to the metal wiring process. The plurality of semiconductor processes are not limited to the processes described above.

Accordingly, a semiconductor device 100 may be formed.

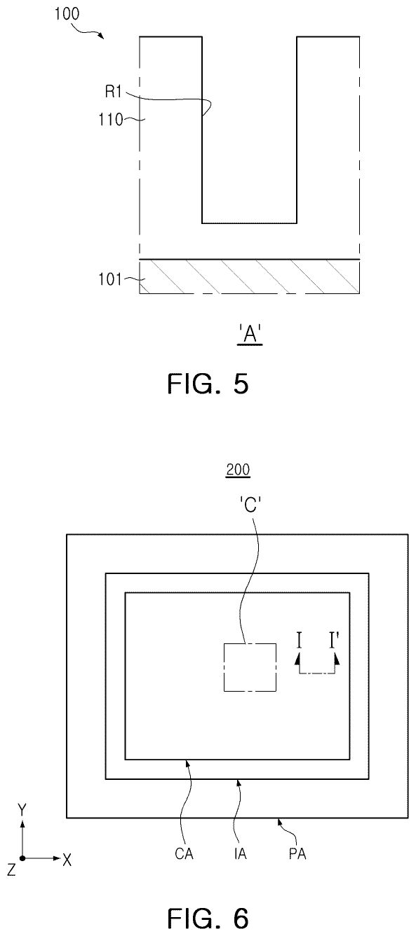

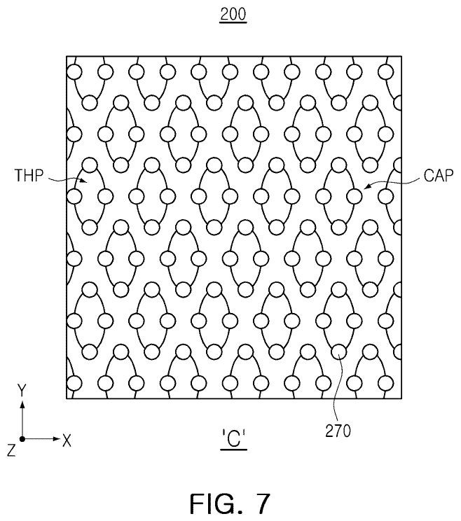

FIG. 6 is a plan view of a semiconductor device according to at least one embodiment.

Referring to FIG. 6, a semiconductor device according to at least one embodiment may include a cell area CA, an interface area IA, and a peripheral circuit area PA. The peripheral circuit area PA may be disposed to surround the cell area CA, and the interface area IA may be disposed between the cell area CA and the peripheral circuit area PA. The cell area CA may refer to an area where memory cells of a Dynamic Random Access Memory (DRAM) device are disposed, and the peripheral circuit area PA may be an area where word line drivers, sense amplifiers, row and column decoders, and control circuits are disposed. The interface area IA may be an area for electrically connecting the cell area CA to the peripheral circuit area PA.

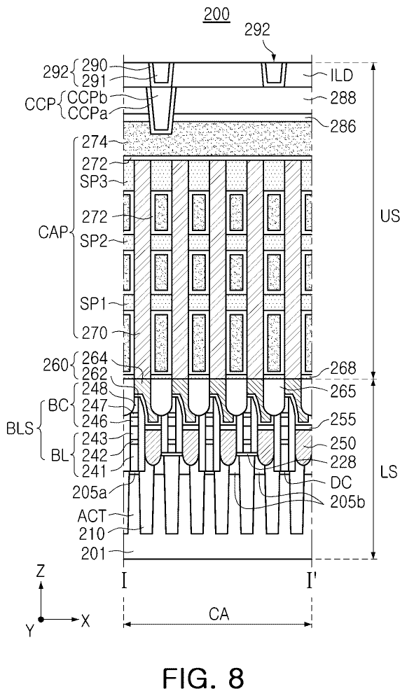

FIG. 7 is a partially enlarged view of the semiconductor device illustrated in FIG. 6, and corresponds to area C. FIG. 8 is a vertical cross-sectional view taken along line I-I′ of the semiconductor device illustrated in FIG. 6.

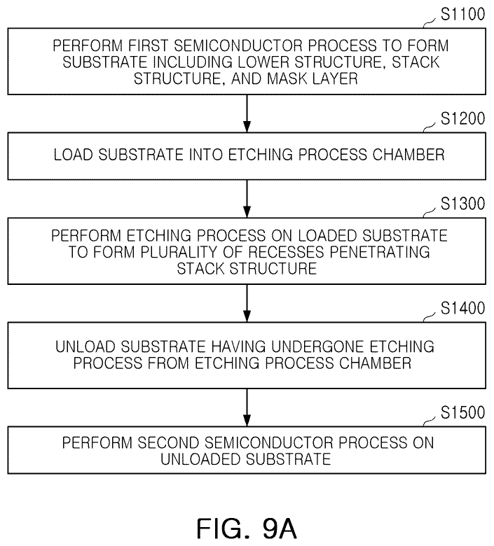

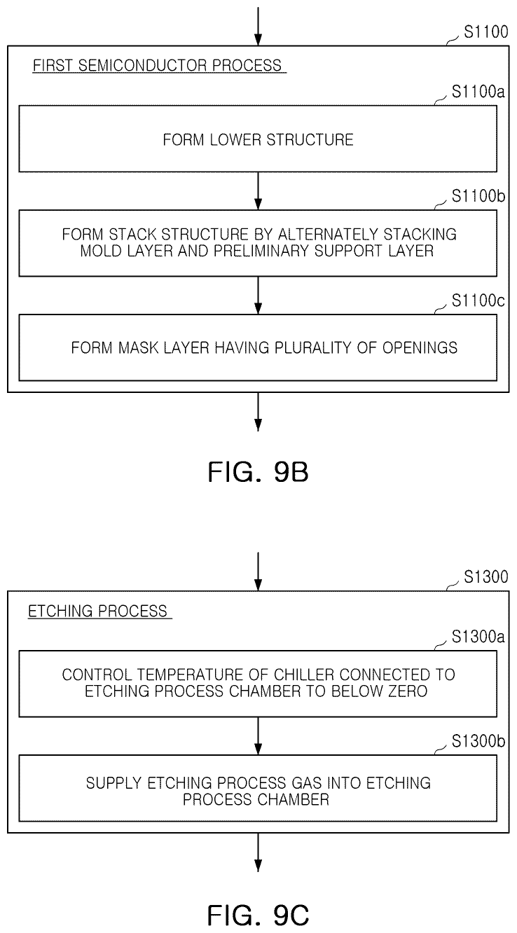

Referring to FIG. 8 and FIG. 9, a semiconductor device 200 may include a substrate 201 including active regions ACT disposed in a cell area CA, a device isolation layer 210 defining the active regions ACT within the substrate 201, a bit line structure BLS disposed on the substrate 201 and including a bit line BL, a data storage structure CAP on the bit line structure BLS, and a plurality of interlayer insulating layers 286, 288 and ILD on the data storage structure CAP.

The data storage structure CAP may store information and may be, for example, a capacitor structure of a DRAM. In the cell area CA, the semiconductor device 200 may further include a lower conductive pattern 250 on the active region ACT, an upper conductive pattern 260 on the lower conductive pattern 250, and an insulating pattern 265 penetrating the upper conductive pattern 260.

Although not illustrated, the semiconductor device 200 may further include a word line that is disposed in the cell area CA and embedded in the substrate 201.

The semiconductor device 200 may include, for example, a cell array of a Dynamic Random Access Memory (DRAM). For example, a bit line BL may be connected to a first impurity region 205a of the active region ACT, and a second impurity region 205b of the active region ACT may be electrically connected to a data storage structure CAP on the upper conductive pattern 260 through the lower and upper conductive patterns 250 and 260.

The data storage structure CAP may be a capacitor configured to store information in a memory such as a DRAM. The data storage structure CAP may be electrically connected to the conductive region 250 and 260 on a lower structure including a conductive region 250 and 260, for example, a lower and upper conductive pattern 250 and 260. In this case, the lower structure may include a substrate 201, a word line, a bit line structure BLS, and the like.

The data storage structure CAP may include first electrode structures 270, a dielectric layer 272 on the first electrode structures 270, and a second electrode structure 274 on the dielectric layer 272. The data storage structure CAP may further include support layers SP1, SP2 and SP3. The first electrode structures 270 may be lower electrodes, and the second electrode structures 274 may be upper electrodes.

The substrate 201 may include a semiconductor material, such as a group IV semiconductor, a group III-V compound semiconductor, or a group II-VI compound semiconductor. For example, the group IV semiconductor may include silicon, germanium, or silicon-germanium. The substrate 201 may further include impurities. The substrate 201 may be a silicon substrate, a silicon-on-insulator (SOI) substrate, a germanium substrate, a germanium-on-insulator (GOI) substrate, a silicon-germanium substrate, or a substrate including an epitaxial layer.

Active regions ACT may be defined within the substrate 201 by a device isolation layer 210. The active region ACT may have first and second impurity regions 205a and 205b of a predetermined depth from the upper surface of the substrate 201. The first and second impurity regions 205a and 205b may be spaced apart from each other. The first and second impurity regions 205a and 205b may be provided as source/drain regions of a transistor configured by a word line. The source region and the drain region are formed by the first and second impurity regions 205a and 205b by doping or ion implantation of the same and/or substantially similar impurities, and may be referred to interchangeably depending on the circuit configuration of the transistor to be finally formed. The impurities may include impurities having a conductivity type opposite to that of the substrate 201. In example embodiments, the depths of the first and second impurity regions 205a and 205b in the source region and the drain region may be different from each other.

The device isolation layer 210 may be formed by a shallow trench isolation (STI) process. The device isolation layer 210 may surround the active regions ACT for electrical isolation thereof from each other. The device isolation layer 210 may be formed of an insulating material, for example, silicon oxide, silicon nitride, or a combination thereof.

Although not illustrated, the word line may be disposed to extend across the active region ACT in a first direction (X). For example, a pair of adjacent word lines may be disposed to extend across one active region ACT. The word line may form a gate of a buried channel array transistor (BCAT), but is not limited thereto.

The bit line structure BLS may extend perpendicularly to the word line in one direction, for example, in a second direction (Y). The bit line structure BLS may include a bit line BL and a bit line capping pattern BC on the bit line BL.

The bit line BL may include a first conductive pattern 241, a second conductive pattern 242, and a third conductive pattern 243 that are sequentially stacked. The bit line capping pattern BC may be disposed on the third conductive pattern 243. A buffer insulating layer 228 may be disposed between the first conductive pattern 241 and the substrate 201, and a portion of the first conductive pattern 241 (hereinafter, a bit line contact pattern DC) may be in contact with a first impurity region 205a of an active region ACT. The bit line BL may be electrically connected to the first impurity region 205a through the bit line contact pattern DC. The lower surface of the bit line contact pattern DC may be positioned at a level lower than the upper surface of the substrate 201 and may be positioned at a level higher than the upper surface of the word line. In at least one embodiment, the bit line contact pattern DC may be locally positioned within a bit line contact hole formed within the substrate 201 and exposing the first impurity region 205a.

The first conductive pattern 241 may include a conductive and/or semiconductor material such as polycrystalline silicon. The first conductive pattern 241 may be in direct contact with the first impurity region 205a. The second conductive pattern 242 may include a metal-semiconductor compound. The metal-semiconductor compound may be, for example, a layer siliciding a portion of the first conductive pattern 241. For example, the metal-semiconductor compound may include cobalt silicide (CoSi), titanium silicide (TiSi), nickel silicide (NiSi), tungsten silicide (WSi), other metal silicides, and/or a combination thereof. The third conductive pattern 243 may include a metal material such as titanium (Ti), tantalum (Ta), tungsten (W), aluminum (Al), etc. The number of conductive patterns forming the bit line BL, the type of material, and/or the stacking order may vary depending on example embodiments.

The bit line capping pattern BC may include a first capping pattern 246, a second capping pattern 247, and a third capping pattern 248 sequentially stacked on the third conductive pattern 243. The first to third capping patterns 246, 247, and 248 may each include an insulating material, for example, a silicon nitride film. The first to third capping patterns 246, 247 and 248 may be formed of the same and/or different materials, and even if the first to third capping patterns 246, 247 and 248 include the same material, the boundary may be distinguished by the difference in physical properties. The thickness of the second capping pattern 247 may be smaller than the thickness of the first capping pattern 246 and the thickness of the third capping pattern 248, respectively. The number of capping patterns and/or the type of material forming the bit line capping pattern BC may vary depending on example embodiments.

The lower conductive pattern 250 may be connected to one area of the active region ACT, for example, the second impurity region 205b. The lower conductive pattern 250 may be disposed between the bit lines BL. The lower conductive pattern 250 may penetrate the buffer insulating layer 228 and be connected to the second impurity region 205b of the active region ACT. The lower conductive pattern 250 may be in direct contact with the second impurity region 205b. The lower surface of the lower conductive pattern 250 may be positioned at a level lower than the upper surface of the substrate 201 and at a level higher than the lower surface of the bit line contact pattern DC. The lower conductive pattern 250 may be insulated from the bit line contact pattern DC. The lower conductive pattern 250 may be formed of a conductive material, and may include, for example, at least one of polycrystalline silicon (Si), titanium (Ti), titanium nitride (TiN), tantalum (Ta), tantalum nitride (TaN), tungsten (W), tungsten nitride (WN), aluminum (Al), and/or the like. In example embodiments, the lower conductive pattern 250 may include a plurality of layers.

A metal-semiconductor compound layer 255 may be disposed between the lower conductive pattern 250 and the upper conductive pattern 260. The metal-semiconductor compound layer 255 may be, for example, a layer that silicides a portion of the lower conductive pattern 250 when the lower conductive pattern 250 includes a semiconductor material. The metal-semiconductor compound layer 255 may include, for example, cobalt silicide (CoSi), titanium silicide (TiSi), nickel silicide (NiSi), tungsten silicide (WSi), other metal silicides, and/or a combination thereof. According to example embodiments, the metal-semiconductor compound layer 255 may be omitted.

The upper conductive pattern 260 may be disposed on the lower conductive pattern 250. The upper conductive pattern 260 may cover the upper surface of the metal-semiconductor compound layer 255. The upper conductive pattern 260 may include a barrier layer 262 and a conductive layer 264. The barrier layer 262 may cover a lower surface and side surfaces of the conductive layer 264. The barrier layer 262 may include at least one of a metal nitride, for example, titanium nitride (TiN), tantalum nitride (TaN), tungsten nitride (WN), and/or the like. The conductive layer 264 may include at least one of a conductive material, for example, polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), tungsten nitride (WN), and/or the like.

The insulating patterns 265 may be disposed to penetrate the upper conductive pattern 260. The upper conductive pattern 260 may be separated into a plurality of pieces by the insulating patterns 265. The insulating patterns 265 may include at least one of an insulating material, for example, silicon oxide, silicon nitride, silicon oxynitride, and/or the like.

The etch stop layer 268 may cover the insulating patterns 265 between the first electrode structures 270. The etch stop layer 268 may also extend further into the interface region IA. The etch stop layer 268 may contact the lower regions of the side surfaces of the first electrode structures 270. The etch stop layer 268 may be disposed below the support layers SP1, SP2 and SP3. The upper surface of the etch stop layer 268 may include a portion that directly contacts the dielectric layer 272. The etch stop layer 268 may include, for example, at least one of silicon nitride and silicon oxynitride.

The first electrode structures 270 may be disposed on the upper conductive patterns 260. The first electrode structures 270 may penetrate the etch stop layer 268 and contact the upper conductive patterns 260. The first electrode structures 270 may be in the form of pillars, but are not limited thereto. The first electrode structures 270 may each include a conductive material, such as a metal nitride, a metal compound, and/or the like. For example, the conductive material may include at least one of niobium nitride (NbN), niobium oxide (NbOx), polycrystalline silicon (Si), iridium (Ir), titanium (Ti), titanium nitride (TiN), titanium silicide nitride (TiSiN), tantalum (Ta), tantalum nitride (TaN), tungsten (W), tungsten nitride (WN), aluminum (Al), or combinations thereof.

The dielectric layer 272 may cover respective side and upper surfaces of the first electrode structures 270, on the surface of the first electrode structures 270. The dielectric layer 272 may be disposed between the first electrode structures 270 and the second electrode structure 274. The dielectric layer 272 may cover the upper and lower surfaces of the support layers SP1, SP2 and SP3. The dielectric layer 272 may cover the upper surface of the etch stop layer 268.

The dielectric layer 272 may include a high-k material, silicon oxide, silicon nitride, combinations thereof, and/or the like. According to example embodiments, the dielectric layer 272 may include an oxide, nitride, silicide, oxynitride, or silicide-oxynitride including at least one of titanium (Ti), tantalum (Ta), hafnium (Hf), aluminum (Al), zirconium (Zr) and lanthanum (La) doped with fluorine (F), combinations thereof, and/or the like.

The second electrode structure 274 may be disposed on the dielectric layer 272. The second electrode structure 274 may fill the space between the plurality of first electrode structures 270 and the space between the support layers SP1, SP2 and SP3. In at least one embodiment, the dielectric layer 272 and the second electrode structure 274 may extend further into the interface area IA. The second electrode structure 274 may include a conductive material.

For example, second electrode structure 274 may be formed of a single layer or multiple layers. In at least one embodiment, the second electrode structure 274 may be in direct contact with the dielectric layer 272 and may include a first material layer formed along the dielectric layer 272 and a second material layer covering the first material layer. The first material layer may include a doped semiconductor, a metal, a conductive metal nitride, a metal-semiconductor compound, a conductive metal oxide, or combinations thereof. The second material layer may include a silicon material and/or a silicon-germanium material. For example, the second material layer may include a doped silicon material and/or a doped silicon-germanium material.

In at least one embodiment, the second electrode structure 274 may further include a protective material layer that may prevent natural oxidation of the second electrode structure 274 and oxidation by the dielectric layer 272. For example, the protective material layer may be covered by the first material layer and may be in direct contact with the dielectric layer 272. The protective material layer may include at least one of a metal, a metal-silicon oxide, a metal-silicon nitride, or a metal-silicon oxynitride.

The support layers SP1, SP2 and SP3 may include a first support layer SP1, a second support layer SP2 on the first support layer SP1, and a third support layer (SP3 on the second support layer SP2. The support layers SP1, SP2 and SP3 may be disposed spaced apart from the substrate 201 in a direction perpendicular to the upper surface of the substrate 201. The support layers SP1, SP2 and SP3 are in contact with the first electrode structures 270 and may extend in a direction parallel to the upper surface of the substrate 201.

The support layers SP1, SP2 and SP3 may be layers that support the first electrode structures 270 having a high aspect ratio. The support layers SP1, SP2 and SP3 may each include, for example, at least one of silicon nitride and silicon oxynitride, or a material similar thereto. The number, thickness, and/or arrangement relationship of the support layers SP1, SP2 and SP3 are not limited to those illustrated and may be variously changed according to example embodiments.

Referring to FIG. 7, the first electrode structures 270 may have a regular arrangement in a plan view viewed from above. In example embodiments, the first electrode structures 270 may be disposed spaced apart from each other by a predetermined distance along the first direction (X) and may be disposed in a zigzag manner along the second direction (Y). For example, the first electrode structures 270 may be disposed in a honeycomb structure. However, the arrangement of the first electrode structures 270 is not limited thereto.

A through-hole pattern THP may be disposed between a plurality of adjacent first electrode structures 270. In some example embodiments, as illustrated in the semiconductor device 200 of FIG. 7, one through-hole pattern THP may be disposed between four adjacent first electrode structures 270. However, the through-hole pattern THP is not limited thereto.

The semiconductor device 200 may further include a lower interlayer insulating layer 286 and an upper interlayer insulating layer 288 covering the data storage structure CAP. The lower interlayer insulating layer 286 may cover the second electrode structure 274. The upper interlayer insulating layer 288 may be disposed on the lower interlayer insulating layer 286. The upper interlayer insulating layer 288 may cover the lower interlayer insulating layer 286.

The lower interlayer insulating layer 286 and the upper interlayer insulating layer 288 may include silicon oxide, silicon nitride, silicon oxynitride, or combinations thereof. In at least one embodiment, the lower interlayer insulating layer 286 and the upper interlayer insulating layer 288 may include silicon oxide, and even if the lower interlayer insulating layer 286 includes the same material as the upper interlayer insulating layer 288, a boundary therebetween may be distinguished. The upper surface of the upper interlayer insulating layer 288 may be flat, for example, parallel to the upper surface of the substrate 201.

The semiconductor device 200 may further include a cell contact plug CCP, an interlayer insulating layer ILD, and a plurality of upper contact plugs 292 on the lower and upper interlayer insulating layers 286, 288. The cell contact plug CCP may penetrate the upper interlayer insulating layer 288 and may be connected to the data storage structure CAP. For example, the cell contact plug CCP may penetrate the plate layer PL and may be connected to the second electrode structure 274. The lower surface of the cell contact plug CCP may be located at a lower level than the upper surface of the second electrode structure 274. The upper surface of the cell contact plug CCP may be coplanar with the upper surface of the upper interlayer insulating layer 288. The cell contact plug CCP may include a barrier layer CCPa and a conductive layer CCPb on the barrier layer CCPa. A side of the cell contact plug CCP may be in contact with the upper interlayer insulating layer 288, may not be in contact with the lower interlayer insulating layer 286, and may be spaced apart from the lower interlayer insulating layer 286.

An interlayer insulating layer ILD may be disposed on the upper interlayer insulating layer 288. The interlayer insulating layer ILD may cover the cell contact plug CCP and the upper interlayer insulating layer 288. The interlayer insulating layer ILD may include silicon oxide.

A plurality of upper contact plugs 292 may penetrate the interlayer insulating layer ILD, and at least one of the plurality of upper contact plugs 292 may be connected to the cell contact plug CCP. The plurality of upper contact plugs 292 may each include a barrier layer 290 and a conductive layer 291 on the barrier layer 290. The lower surfaces of the plurality of upper contact plugs 292 may be flat, for example, parallel to the upper surface of the substrate 201. The lower surfaces of the plurality of upper contact plugs 292 may be positioned at the same level.

The barrier layer CCPa and the barrier layer 290 may include a metal nitride such as titanium nitride (TiN). The conductive layer CCPb and the conductive layer 291 may include a conductive material such as tungsten (W) or tungsten nitride (WN).

FIGS. 9A to 9C are flowcharts illustrating a method of manufacturing a semiconductor device according to at least one embodiment according to the process sequence.

Referring to FIG. 9A, manufacturing a semiconductor device 200 may include performing a first semiconductor process to form a substrate including a lower structure, a stack structure, and a mask layer (S1100), loading the substrate into an etching process chamber (S1200), performing an etching process on the loaded substrate to form a plurality of recesses penetrating the stack structure (S1300), unloading the substrate on which the etching process has been performed from the etching process chamber (S1400), and performing a second semiconductor process on the unloaded substrate (S1500).

Referring to FIG. 9B, in operation S1100, performing the first semiconductor process may include forming a lower structure (S1100a), alternately stacking a mold layer and a preliminary support layer to form a stack structure (S1100b), and forming a mask layer having a plurality of openings on the stack structure (S1100c).

Referring to FIG. 9C, in operation S1300, performing the etching process may include controlling the temperature of a chiller connected to the etching process chamber to below zero (S1300a), and supplying an etching process gas into the etching process chamber (S1300b).

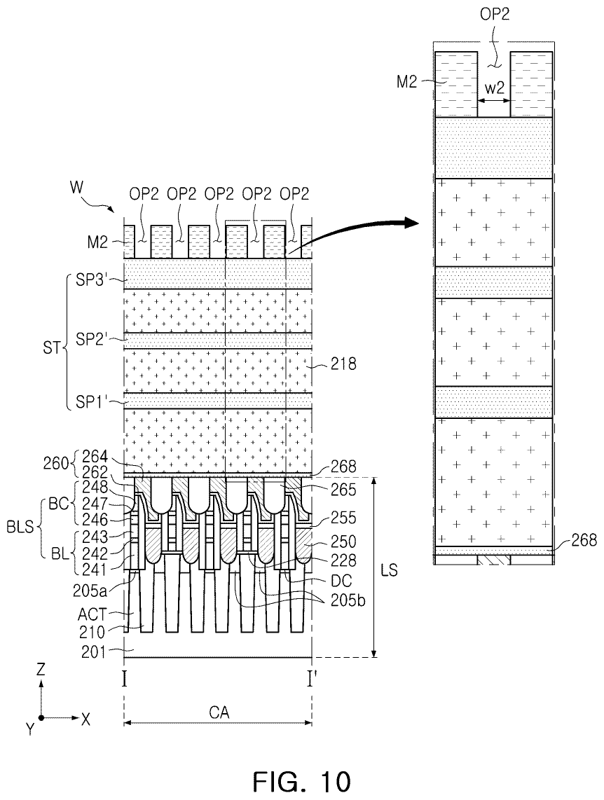

Each of the operations (S1100-S1500) may be described with reference to FIGS. 10 to 13.

At least a part of manufacturing the semiconductor device 200 may be performed in the substrate processing apparatus 1 described with reference to FIG. 1.

FIGS. 10 to 13 are cross-sectional views illustrating a method of manufacturing a semiconductor device according to at least one embodiment. FIGS. 10 to 13 may be processing diagrams based on the flowcharts of FIGS. 9A to 9C.

Referring to FIGS. 9A and 10, a first semiconductor process may be performed to form a substrate W including a lower structure LS, a stack structure ST, and a mask layer M2 (S1100).

Referring to FIG. 9B, the first semiconductor process may include forming a lower structure LS (S1100a).

Referring to FIG. 10, a lower structure LS including a substrate 201, a word line, a bit line structure BLS, and the like may be formed.

Referring to FIG. 9B, the first semiconductor process may include forming a stack structure ST by alternately stacking mold layers 218 and preliminary support layers SP1′, SP2′ and SP3′ on a lower structure LS (S1100b).

Referring to FIG. 10, a stack structure ST may be formed on the lower structure LS. The stack structure ST may be formed by conformally forming an etch stop layer 268 on the lower structure and alternately stacking mold layers 218 and preliminary support layers SP1′, SP2′ and SP3′ on the etch stop layer 268. The molded structure ST may be disposed in the cell area CA, the interface area IA, and the peripheral circuit area PA (see FIG. 6).

The mold layers 218 may include an insulating oxide, and the preliminary support layers SP1′, SP2′ and SP3′ may include an insulating nitride. The mold layers 218 may include, for example, silicon oxide, and the preliminary support layers SP1′, SP2′ and SP3′ may include silicon nitride.

Referring to FIG. 9B, the first semiconductor process may include forming a mask layer M2 having a plurality of openings OP2 on the stack structure ST (S1100c).

Referring to FIG. 10, a patterned mask layer M2 may be provided on the stack structure ST. The patterned mask layer M2 may have an opening OP2 of a second width w2. The mask layer M2 may be a metal-containing mask layer formed of a metal-containing material. The metal-containing material may include a transition metal. The metal-containing material may include, for example, titanium nitride, tungsten, tungsten carbide, and/or the like.

The opening OP2 may include a plurality of openings formed spaced apart in a direction parallel to the upper surface of the substrate 201. The second width w2 may be substantially the same as the first width w1 described with reference to FIG. 3. The second width w2 may be about 20 nm or less. In at least one embodiment, the second width w2 may be in a range of about 5 nm or more and about 20 nm or less. In at least one embodiment, the second width w2 may be in a range of about 7 nm or more and about 20 nm or less.

Referring again to FIG. 9A, the substrate W may be loaded onto the electrostatic chuck of the process chamber 10 through the gate (refer to ‘14’ of FIG. 1) (S1200).

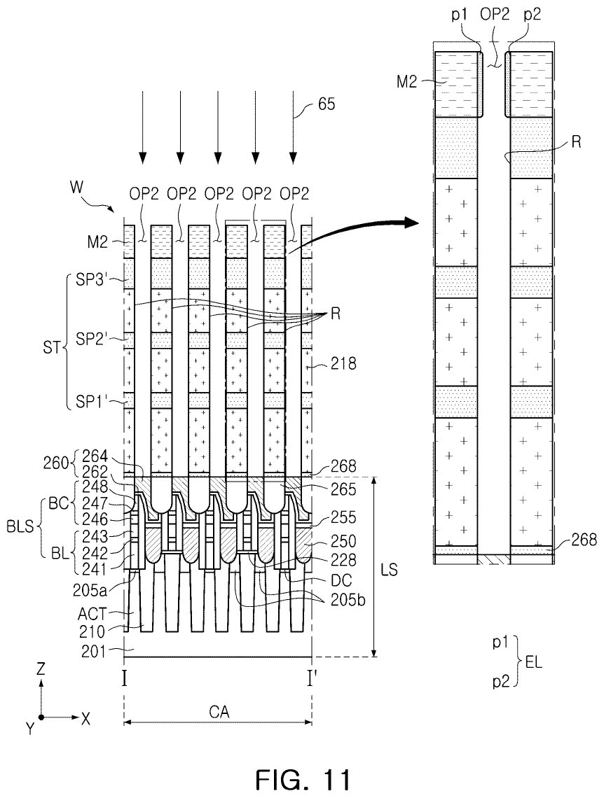

Referring to FIGS. 9A and 11, an etching process may be performed on the loaded substrate W to form a plurality of recesses R penetrating at least a portion of the stack structure ST (S1300).

Referring to FIG. 9C, the etching process may include controlling the temperature of the chiller 80 connected to the process chamber 10 to be below zero (S1300a).

Referring to FIGS. 1 and 9C, the operation (S1300a) of controlling the temperature of the chiller 80 connected to the process chamber 10 to below zero (0° C.) may be performed by measuring and determining the temperature of the chiller 80 using a temperature detection signal output from a temperature detection sensor that detects the temperature of the chiller 80. The temperature may be a temperature within a range of about −80° C. to about −35° C.

The coolant output from the chiller 80 circulates through the coolant inlet pipe, the coolant path 85, and the coolant outlet pipe, and the substrate W loaded on the electrostatic chuck may be cooled by the coolant.

The cooling temperature of the loaded substrate W may be formed lower than the temperature of the chiller 80. In at least one embodiment, the surface temperature of the loaded substrate W may be a temperature within a range of about −60° C. to about 0° C. In at least one embodiment, the surface temperature of the loaded substrate W may be a temperature within a range of about −40° C. to about −10° C. In at least one embodiment, the median value of the surface temperature of the loaded substrate W may be −25° C. When the surface temperature of the loaded substrate W is below zero, the etching process may be performed at a higher etching rate compared to when the surface temperature of the loaded substrate W is at room temperature.

Referring to FIGS. 9C and 11, the etching process may include supplying a process gas 65 into the process chamber 10 (S1300b).

Referring to FIGS. 1, 9C, and 11, a process gas 65 may be supplied into the process chamber 10 through a gas supply pipe 70. The process gas 65 may be a gas mixture in which first to third process gases 61P, 62P and 63P of first to third process gas supply sources 61, 62 and 63 are mixed.

The process gas 65 may be the same as (and/or substantially similar to) the process gas 65 described with reference to FIG. 2c.

The first process gas 61P may include a material that etches the stack structure ST. The first process gas 61P may include a hydrogen-containing gas. The first process gas 61P may include, for example, at least one of hydrogen gas or hydrofluoric acid.

The second process gas 62P may include a material that assists the etching process. The second process gas 62P may include a fluorine-containing gas. The second process gas 62P may include at least one of different first gas components 62P1 or second gas components 62P2. The first gas component 62P1 may contain boron. The first gas component 62P1 may include, for example, boron trifluoride (BF₃). The second gas component 62P2 may contain nitrogen. The second gas component 62P2 may include, for example, nitrogen trifluoride (NF₃).

The third process gas 63P may include a substance for controlling the concentration of the first and second process gases 61P and 62P. The third process gas 63P may include, for example, an inert gas. The third process gas supply source 63 may be referred to as an inert gas supply source.

The mole fraction of the second process gas 62P relative to the process gas 65 may be about 30 mol % or less. In at least one embodiment, the mole fraction may be in a range of about 0.01 mol % to about 30 mol %. In at least one embodiment, the mole fraction may be in a range of about 0.01 mol % to about 10 mol %. In at least one embodiment, the molar fraction may be in the range of about 0.03 mol % to about 5 mol %.

The molar ratio of the second process gas 61P to the first process gas 62P may be about 0.2 times or less. In at least one embodiment, the molar ratio may be in the range of about 0.01 times to about 0.2 times. The molar ratio may be in the range of about 0.03 times to about 0.1 times.

When the second process gas 62P includes both the first and second gas components 62P1 and 62P2, the molar ratio of the first gas component 62P1 to the second gas component 62P2 may be about 1.0 times or more. In at least one embodiment, the molar ratio of the first gas component 62P1 to the second gas component 62P2 may be in the range of about 1.0 times to about 3.0 times. In at least one embodiment, the molar ratio of the first gas component 62P1 to the second gas component 62P2 may be in a range of about 1.5 times to about 2.5 times. In at least one embodiment, the molar ratio of the first gas component 62P1 to the second gas component 62P2 may be about 2.0 times.

Meanwhile, the process gas 65 may not include a carbon-containing gas.

Referring again to FIGS. 9A and 11, a plurality of recesses R penetrating at least a portion of the stack structure ST may be formed by the process gas 65 (S1300).

A plurality of recesses R may be formed by the process gas 65. The plurality of recesses R may respectively be formed by etching the stack structure ST exposed by the opening OP2 by the first process gas 61P.

Similar to what was described with reference to FIGS. 2A and 4A, first by-products bp may be formed. The first by-products bp may be a gaseous material formed when the stack structure ST is etched by the first process gas 61P. The first by-products bp may include, for example, a nitrogen-containing gas b1 or an oxygen-containing gas b2. At least a portion bl of the first by-products bp may be derived from the preliminary support layers SP1′, SP2′ and SP3′. The nitrogen-containing gas b1 may include, for example, ammonia (NH₃). At least a portion b2 of the first by-products bp may be derived from the mold layers 218. The gas b2 containing oxygen may include, for example, water vapor (H₂O).

Similarly to what was described with reference to FIG. 2A and FIG. 4A, an edge layer EL may be formed by the process gas 65. The edge layer EL may be formed on the sidewall of the opening OP2. The edge layer EL may be formed by at least a portion of the second process gas 62P reacting with the material of the mask layer M2. In another aspect, the edge layer EL may be formed by at least a portion of the second process gas 62P physically and/or chemically bonding with the mask layer M2. Additionally, the first by-products bp may react with the metal material of the mask layer M2, thereby forming a residue layer formed of a metal oxide, a metal nitride, or a metal oxynitride on the sidewall of the opening OP2. Accordingly, the second width (‘w2’ in FIG. 10) of the opening OP2 may be narrowed or completely closed. Therefore, the edge layer EL may significantly reduce or prevent the phenomenon of the opening being blocked, so that the etching rate for the stack structure ST may be maintained. The edge layer EL may include, for example, boron nitride.

Similarly to what was described with reference to FIG. 2A and FIG. 4A, at least a portion of the second process gas 62P and the first by-products bp may react to form second by-products. At least a portion of the second process gas 62P may react with the first by-products bp, thereby significantly reducing or eliminating the amount of the first by-products bp that may react with the material of the mask layer M2. The second by-products may include, for example, at least one of boron trifluoride ammonia complex (BF₃·NH₃) or boric acid (H₃BO₃).

The edge layer EL may include a first portion p1 formed on a first side of the opening OP2 and a second portion p2 formed on a second side facing the first side. The minimum distance between the first and second portions p1 and p2 may be substantially the same as the first distance L1 described with reference to FIG. 4B.

In the present embodiment, the minimum distance between the first and second portions p1 and p2 may be about 0.5 or more times the second width (see ‘w2’ of FIG. 10). In at least one embodiment, the minimum distance may be in a range of about 0.5 times to about 0.9 times the second width w2. In at least one embodiment, the minimum distance may be in a range of about 0.5 to about 0.8 times the second width w2.

The first thickness d1, which is at least one maximum thickness of the first and second portions p1 and p2, may be about 5 nm or less. In at least one embodiment, the first thickness d1 may be in a range of about 1 nm to about 5 nm. In at least one embodiment, the first thickness dl may be in a range of about 2 nm to about 5 nm.

Thereafter, referring back to FIG. 9A, the substrate W on which the etching process has been performed may be unloaded from the electrostatic chuck and removed from the process chamber 10 through the gate (refer to ‘14’ of FIG. 1) (S1400).

Referring to FIG. 9A, a second semiconductor process may be performed on the unloaded substrate W to form a semiconductor device 200 (S1500).

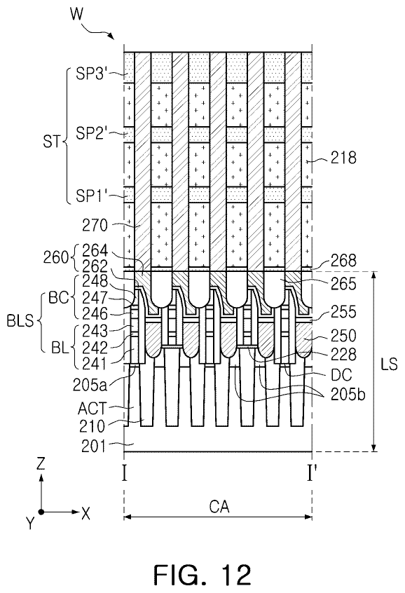

Referring to FIG. 12, the second semiconductor process may include forming first electrode structures 270 by filling a conductive material into a plurality of recesses R. The first electrode structures 270 may be disposed in a honeycomb structure as illustrated in FIG. 7.

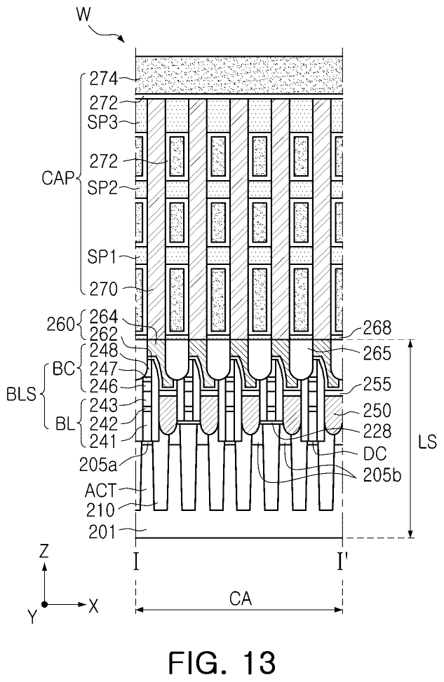

Referring to FIG. 13, the second semiconductor process may include forming a dielectric layer 272 and second electrode structures 274 to form a data storage structure ST.

The stack structure ST may be removed (not illustrated) in the interface area IA and the peripheral circuit area PA. For example, the mold layers 218 and the preliminary support layers SP1′, SP2′ and SP3′ may be etched in the interface area IA and the peripheral circuit area PA, thereby forming the support layers SP1, SP2 and SP3 in the cell area CA.

Thereafter, the mold layers 218 may be selectively removed. The dielectric layer 272 may be conformally formed along the surfaces of the first electrode structures 270 and the support layers SP1, SP2 and SP3. The dielectric layer 272 may also cover the etch-preventing layer 268.

Afterwards, a second electrode structure 274 covering the dielectric layer 272 may be formed. The second electrode structure 274 may fill the space between the first electrode structures 270 and may cover the first electrode structures 270 and the support layers SP1, SP2 and SP3. The first electrode structures 270, the dielectric layer 272, and the second electrode structure 274 may form a data storage structure CAP.

Next, referring to FIG. 8, a lower interlayer insulating layer 286 may be formed on the data storage structure CAP. The lower interlayer insulating layer 286 may be in contact with the second electrode structure 274. An upper interlayer insulating layer 288 may be formed on the lower interlayer insulating layer 286. A cell contact plug CCP may be connected to a data storage structure CAP by penetrating the lower interlayer insulating layer 286 and the upper interlayer insulating layer 288.

Afterwards, a BEOL process is performed so that an interlayer insulating layer ILD and upper contact plugs 292 are formed on the upper interlayer insulating layer 288, thereby manufacturing a semiconductor device 200.

As set forth above, according to example embodiments, a semiconductor device having improved electrical characteristics and/or reliability is provided.

In detail, by using process gas containing at least one required gas component having a required molar fraction relative to the entire process gas, a phenomenon of blocking of an opening in a mask layer may be significantly reduced or prevented, thereby providing a semiconductor device having improved electrical characteristics and/or reliability.

While example embodiments have been illustrated and described above, it will be apparent to those skilled in the art that modifications and variations could be made without departing from the scope of the present inventive concepts as defined by the appended claims.

What is claimed is:

1. A method of manufacturing a semiconductor device, comprising:
providing a substrate comprising a molded structure and a mask layer on the molded structure, the mask layer having an opening of a first width;
loading the substrate into an etching process chamber;
performing an etching process on the loaded substrate such that a plurality of recesses penetrating at least a portion of the molded structure are formed;
unloading the substrate having undergone the etching process from the etching process chamber; and
performing a semiconductor process on the unloaded substrate,
wherein the performing the etching process comprises supplying an etching process gas comprising a first process gas and a second process gas into the etching process chamber through a gas supply source connected to the etching process chamber, the second process gas including a fluorine-containing gas, and
wherein, in the forming the plurality of recesses, first by-products are formed, and second by-products are formed by a reaction of at least a portion of the first by-products and the second process gas.

2. The method of claim 1, wherein the first width is in a range of about 5 nm to about 20 nm.

3. The method of claim 1, wherein the mask layer includes a transition metal.

4. The method of claim 1, wherein the first process gas includes at least one of hydrogen or hydrofluoric acid.

5. The method of claim 1, wherein the molded structure includes at least one of an oxide or a nitride, and
the first by-products are formed by a reaction of the first process gas and the molded structure.

6. The method of claim 1, wherein the first by-products include at least one of water vapor (H₂O) or ammonia (NH₃).

7. The method of claim 1, wherein the fluorine-containing gas of the second process gas includes at least one of boron trifluoride (BF₃) or nitrogen trifluoride (NF₃).

8. The method of claim 1, wherein a mole fraction of the second process gas relative to the etching process gas is in a range of about 0.01 mol % to about 30 mol %.

9. The method of claim 1, wherein the second by-products include at least one of boron trifluoride ammonia complex (BF₃·NH₃) or boric acid (H₃BO₃).

10. The method of claim 1, wherein the supplying the etching process gas includes forming an edge layer on a sidewall of the opening.

11. The method of claim 10, wherein, in a cross-sectional view, the edge layer includes:
a first portion formed on a first side of the opening; and
a second portion formed on a second side facing the first side, and
wherein at least one of the first and second portions has a maximum thickness in a range of about 1 nm to about 5 nm.

12. The method of claim 11, wherein the maximum thickness of at least one of the first and second portions is defined in an upper region of the edge layer, relative to the substrate.

13. The method of claim 10, wherein, in a cross-sectional view, the edge layer includes:
a first portion formed on a first side of the opening; and
a second portion formed on a second side facing the first side, and
wherein a minimum distance between the first and second portions is in a range of about 0.5 times to about 0.9 times the first width of the opening.

14. A method of manufacturing a semiconductor device, comprising:
providing a substrate comprising a lower structure, a stack structure including first layers and second layers alternately stacked on the lower structure, and a mask layer on the stack structure, the mask having an opening of a first width;
loading the substrate into an etching process chamber;
performing an etching process on the loaded substrate such that a plurality of recesses penetrating at least a portion of the stack structure are formed;
unloading the substrate having undergone the etching process from the etching process chamber; and
performing a semiconductor process on the unloaded substrate,
wherein the performing the etching process includes
controlling a temperature of a chiller connected to the etching process chamber to be below zero degrees Celsius (0° C.), and
supplying an etching process gas including a first process gas and a second process gas the etching process chamber through a gas supply source connected to the etching process chamber, the second process gas including at least one of boron trifluoride (BF₃) or nitrogen trifluoride (NF₃), and
wherein, in forming the plurality of recesses, first by-products are formed, and second by-products are formed by a reaction of at least a portion of the first by-products and the second process gas.

15. The method of claim 14, wherein the first width is in a range of about 7 nm to about 20 nm or less.

16. The method of claim 14, wherein the first layers include silicon oxide,
the second layers include silicon nitride, and
the first by-products include water vapor (H₂O) and ammonia (NH₃).

17. The method of claim 14, wherein the controlling a temperature of a chiller includes reducing a surface temperature of the loaded substrate to be in a range of about −40° C. to about −10° C.

18. The method of claim 14, wherein a molar ratio of the second process gas to the first process gas is in a range of about 0.01 times to about 0.2 times.

19. The method of claim 14, wherein the semiconductor process includes:
removing the mask layer of the substrate; and
filling the plurality of recesses with a conductive material.

20. A method of manufacturing a semiconductor device, comprising:
providing a substrate comprising a lower structure, a stack structure including first layers and second layers alternately stacked on the lower structure, and a mask layer on the stack structure, the mask having an opening;
loading the substrate into an etching process chamber;
performing an etching process on the loaded substrate such that a plurality of recesses penetrating at least a portion of the stack structure are formed;
unloading the substrate having undergone the etching process from the etching process chamber; and
performing a semiconductor process on the unloaded substrate,
wherein the performing the etching process includes
controlling a temperature of a chiller connected to the etching process chamber to be below zero degrees Celsius (0° C.), and
supplying an etching process gas including a first process gas and a second process gas into the etching process chamber through a gas supply source connected to the etching process chamber, the first process gas containing at least one of hydrogen or hydrofluoric acid, and the second process gas containing at least one of boron trifluoride (BF₃) or nitrogen trifluoride (NF₃),
wherein, in forming the plurality of recesses, first by-products and second by-products are sequentially formed by forming the plurality of recesses, and
wherein the first by-products are formed by a reaction of the first process gas and the stack structure, and the second by-products are formed by a reaction of at least a portion of the first by-products and the second process gas.
